(19) United States
(12) Patent Application Publication
(10) Pub. No.: US 2025/0185246 A1
(43) Pub. Date: Jun. 5, 2025

(54) MEMORY DEVICE AND METHOD OF MANUFACTURING THE SAME

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/666,196

(22) Filed: May 16, 2024

(30) Foreign Application Priority Data
Dec. 4, 2023 (KR) 10-2023-0173482

(51) Int. Cl. H10B 43/27

(52) U.S. Cl. CPC H10B 43/27

(57) ABSTRACT

Provided herein may be a memory device and a method of manufacturing the same. The memory device may include a first stacked body spaced apart from a second stacked body by a slit, a dummy layer configured to fill a portion of the slit and including a recess formed at a first end of the slit, a plurality of spacers comprising a first spacer and a second spacer, wherein the first spacer is disposed between the dummy layer and the first stacked body, and the second spacer is disposed between the dummy layer and the second stacked body, and a source line disposed over the first stacked body, the second stacked body, the dummy layer, and the spacers. Each of the plurality of spacers may include a protruding portion that extends away from the first stacked body and the second stacked body, and the source line may fill the recess.

### CROSS-REFERENCE TO RELATED APPLICATION

The present application claims priority under 35 U.S.C. § 119(a) to Korean patent application number 10-2023-0173482 filed on Dec. 4, 2023, in the Korean Intellectual Property Office, the entire disclosure of which application is incorporated herein by reference.

### BACKGROUND

### 1. Technical Field

Various embodiments of the present disclosure generally relate to a memory device and a method of manufacturing the memory device, including, but not limited to, a memory device manufactured using a wafer bonding technique and a method of manufacturing the memory device.

### 2. Related Art

Memory devices may include nonvolatile memory devices in which stored data is retained even when power supply is interrupted. The nonvolatile memory devices may be classified as two-dimensional (2D) structures or a three-dimensional (3D) structure according to the structure in which memory cells are arranged. The memory cells of a nonvolatile memory device having a 2D structure may be arranged in a single layer over a substrate, and the memory cells of a nonvolatile memory device having a 3D structure may be vertically stacked over the substrate. Because the degree of integration of the nonvolatile memory device having a 3D structure is higher than the degree of integration of the nonvolatile memory device having a 2D structure, the number of electronic devices using nonvolatile memory devices having a 3D structure has recently increased.

### SUMMARY

An embodiment of the present disclosure may provide for a memory device. The memory device may include a first stacked body spaced apart from a second stacked body by a slit, a dummy layer configured to fill a portion of the slit and including a recess formed at a first end of the slit, a plurality of spacers comprising a first spacer and a second spacer, wherein the first spacer is disposed between the dummy layer and the first stacked body, and the second spacer is disposed between the dummy layer and the second stacked body, and a source line disposed over the first stacked body, the second stacked body, the dummy layer, and the plurality of spacers. Each of the plurality of spacers may include a protruding portion that extends away from the first stacked body and the second stacked body, and the source line may fill the recess.

An embodiment of the present disclosure may provide for a method of manufacturing a memory device. The method may include forming over a first substrate a first structure including a plurality of first material layers alternatively stacked with a plurality of second material layers, forming a slit through the first structure, replacing, through the slit, the plurality of second material layers with a plurality of third material layers, forming a plurality of spacers along an outer periphery of the slit, filling the slit between the spacers with a dummy layer, removing at least a part of the first substrate; forming a recess in the dummy layer by removing a portion of the dummy layer between the spacers, and forming a source line filling the recess between the spacers.

A method comprising forming a first stacked body spaced apart from a second stacked body by a slit; forming a plurality of spacers within the slit and disposed between the first stacked body and the second stacked body; forming a dummy layer between the spacers including a recess formed at a first end of the slit; and forming a source line disposed over the first stacked body, the second stacked body, the dummy layer, and the plurality of spacers, wherein the source line fills the recess.

### BRIEF DESCRIPTION OF THE DRAWINGS

FIG. 1 is a diagram illustrating a memory device according to an embodiment of the present disclosure.

FIG. 2 is a diagram illustrating a memory cell array according to an embodiment of the present disclosure.

FIG. 3 is a diagram illustrating a memory block according to an embodiment of the present disclosure.

FIG. 4 is a view illustrating the cross-section of a memory device including a slit according to an embodiment of the present disclosure.

FIG. 5A through FIG. 5K are views of a semiconductor device formed utilizing a method of manufacturing a memory device including a slit according to an embodiment of the present disclosure.

FIG. 6 is a diagram illustrating an embodiment of a memory card system including a memory device according to the present disclosure.

FIG. 7 is a diagram illustrating an embodiment of a solid state drive (SSD) system including a plurality of memory devices according to the present disclosure.

### DETAILED DESCRIPTION

Specific structural or functional descriptions in the embodiments of the present disclosure introduced in this application are provided as examples that describe embodiments according to the concepts of the present disclosure. The embodiments according to the concepts of the present disclosure may be implemented in various forms and should not be construed as limited to the embodiments described in the present application.

Various embodiments of the present disclosure are described in detail with reference to the accompanying drawings to allow those skilled in the art to which the present disclosure pertains to easily practice the technical aspects of the present disclosure. The cross-hatching throughout the figures illustrates corresponding or similar areas between the figures rather than indicating the materials for the areas.

Terms such as “under,” “upper,” “lower,” “left,” “right,” “upside down,” “upward,” “downward,” “down,” “above,” “vertical,” “horizontal,” and other terms implying spatial relationship are provided only for the purpose of ease of description or reference to a drawing and are not otherwise limiting.

Various embodiments of the present disclosure are directed to a memory device and a method of manufacturing the memory device. The strength of the memory device may be increased, and bending of the memory device may be reduced.

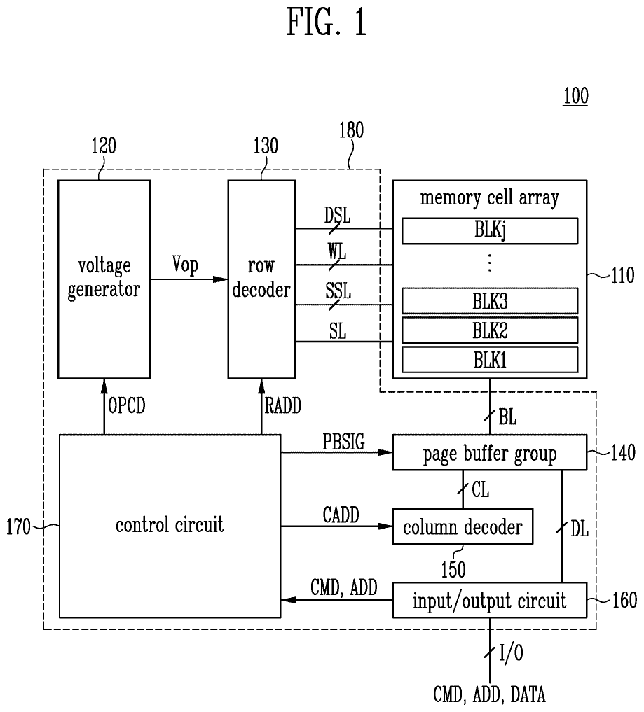

FIG. 1 is a diagram illustrating a memory device according to an embodiment of the present disclosure.

Referring to FIG. 1, a memory device 100 includes a memory cell array 110 and a peripheral circuit 180.

The memory cell array 110 includes memory blocks BLK1 through BLKj, where j is a positive integer. Each of the first memory block BLK1 through the j-th memory blocks BLKj includes memory cells capable of storing data. Drain select lines DSL, word lines WL, source select lines SSL, and a source line SL are coupled to each of the memory blocks BLK1 through BLKj, and bit lines BL are coupled in common to the memory blocks BLK1 to BLKj.

Each of the memory blocks BLK1 through BLKj is formed to have a three-dimensional (3D) structure. Each memory block having a 3D structure includes memory cells stacked over a substrate, for example, in a vertical direction.

According to a program scheme, each memory cell stores 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme.

The peripheral circuit 180 performs a program operation including storing data in the memory cell array 110, a read operation including outputting data stored in the memory cell array 110, and an erase operation including erasing data stored in the memory cell array 110. For example, the peripheral circuit 180 includes a voltage generator 120, a row decoder 130, a page buffer group 140, a column decoder 150, an input/output circuit 160, and a control circuit 170.

The voltage generator 120 generates various operating voltages Vop that are used during a program operation, a read operation, or an erase operation in response to an operation code OPCD. For example, the voltage generator 120 generates program voltages, turn-on voltages, turn-off voltages, negative voltages, precharge voltages, verify voltages, read voltages, pass voltages, and erase voltages in response to the operation code OPCD. The operating voltages Vop generated by the voltage generator 120 are applied to the drain select lines DSL, the word lines WL, the source select lines SSL, and the source line SL of a selected memory block by the row decoder 130.

The program voltages are voltages that are applied to the selected word line among the word lines WL during a program operation and are used to increase the threshold voltages of memory cells coupled to the selected word line. The turn-on voltages are applied to the drain select lines DSL and the source select lines SSL and are used to turn on drain select transistors and source select transistors. The turn-off voltages are applied to the drain select lines DSL and the source select lines SSL and are used to turn off the drain select transistors and the source select transistors. For example, the turn-off voltages may be 0 V. The precharge voltages may be voltages higher than 0 V and are applied to the bit lines during a read operation. The verify voltages are used during a verify operation including determining whether the threshold voltages of selected memory cells are increased to a target level. The verify voltages may be set to various levels according to the target level and are applied to the selected word line.

The read voltages are applied to the selected word line during a read operation performed on the selected memory cells. For example, the read voltages may be set to various levels according to the program scheme for the selected memory cells. The pass voltages are voltages that are applied to unselected word lines among the word lines WL during a program or read operation and are used to turn on memory cells coupled to the unselected word lines. The erase voltages are used during an erase operation including erasing the memory cells included in the selected memory block and are applied to the source line SL.

The row decoder 130 is configured to transfer the operating voltages Vop to the drain select lines DSL, the word lines WL, the source select lines SSL, and the source line SL that are coupled to a memory block selected according to the row address RADD. For example, the row decoder 130 is coupled to the voltage generator 120 through global lines GL and is coupled to the memory blocks BLK1 through BLKj through the drain select lines DSL, the word lines WL, the source select lines SSL, and the source line SL.

The page buffer group 140 includes a plurality (j) of page buffers (not illustrated) coupled to the memory blocks BLK1 through BLKj, respectively. The page buffers are coupled to the memory blocks BLK1 through BLKj through corresponding bit lines BL. During a read operation, the page buffers, in response to page buffer control signals PBSIG, sense the currents or voltages of the bit lines, which currents or voltages vary with the threshold voltages of the selected memory cells and temporarily stores the sensed data.

The column decoder 150 is configured to facilitate data transfer between the page buffer group 140 and the input/output circuit 160 in response to receiving a column address CADD. For example, the column decoder 150 is coupled to the page buffer group 140 through column lines CL and transmits enable signals through the column lines CL. The page buffers included in the page buffer group 140 receive or output data through data lines DL to the input/output circuit 160 in response to the enable signals.

The input/output circuit 160 is configured to receive or output a command CMD, an address ADD, or data through input/output lines I/O. For example, the input/output circuit 160 transmits the command CMD and the address ADD, received from an external controller through the input/output lines I/O, to the control circuit 170, and transmits the data, received from the external controller through the input/output lines I/O, to the page buffer group 140. Alternatively, the input/output circuit 160 outputs data DATA, received from the page buffer group 140, to the external controller through the input/output lines I/O.

The control circuit 170 outputs the operation code OPCD, the row address RADD, the page buffer control signals PBSIG, and the column address CADD in response to the command CMD and the address ADD. For example, when the command CMD input to the control circuit 170 is a command corresponding to a program operation, the control circuit 170 controls the devices included in the peripheral circuit 180 such that the program operation is performed on a memory block selected by the address ADD. When the command CMD input to the control circuit 170 is a command corresponding to a read operation, the control circuit 170 controls the devices included in the peripheral circuit 180 such that the read operation is performed on a memory block selected by the address and read data is output. When the command CMD input to the control circuit 170 is a command corresponding to an erase operation, the control circuit 170 controls the devices included in the peripheral circuit 180 such that the erase operation is performed on a selected memory block.

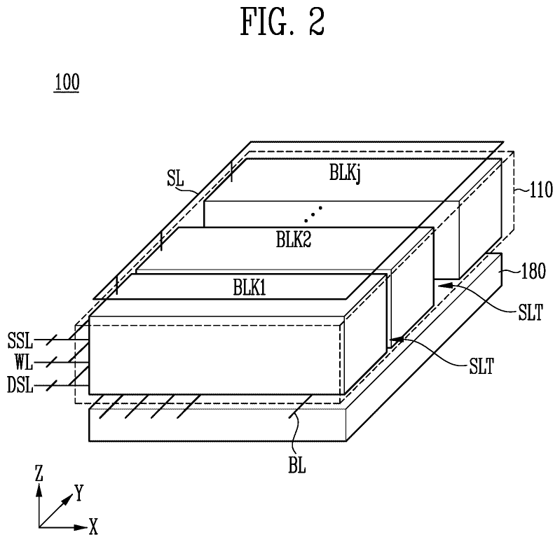

FIG. 2 is a diagram illustrating a memory cell array according to an embodiment of the present disclosure.

Referring to FIG. 2, the memory device 100 includes a peripheral circuit 180 and a memory cell array 110 disposed over the peripheral circuit 180. The memory cell array 110 may be disposed directly on the peripheral circuit 180. The memory cell array 110 may include memory blocks BLK1 through BLKj. Each of the memory blocks BLK1 through BLKj includes cell plugs extending in a Z direction. Each of the cell plugs includes source select transistors, memory cells, and drain select transistors.

Each of the memory blocks BLK1 through BLKj extends in an X direction, as shown in FIG. 2. The memory blocks BLK1 through BLKj are arranged to be spaced apart from each other along a Y direction. The memory blocks BLK1 to BLKj are spaced apart from each other by slits SLT. The slits SLT electrically separate consecutive memory blocks BLK1 to BLKj.

The memory blocks BLK1 through BLKj are disposed between a source line SL and a plurality of bit lines BL. The source line SL is disposed above the f memory blocks BLK1 through BLKj, and the bit lines BL are disposed under or below the first to j-th memory blocks BLK1 through BLKj in the example of FIG. 2. The bit lines BL are disposed between the memory cell array 110 and the peripheral circuit 180. The source line SL is coupled to the cell plugs at the top of the memory blocks BLK1 through BLKj, and the bit lines BL are coupled to the cell plugs at the bottom of the memory blocks BLK1 through BLKj.

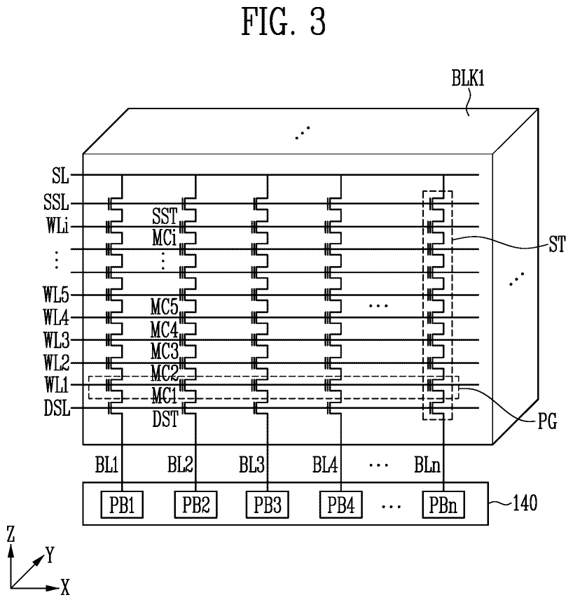

FIG. 3 is a diagram illustrating a memory block according to an embodiment of the present disclosure.

Referring to FIG. 3, the first memory block BLK1 among the BLK1 through BLKj, shown in FIG. 2, is illustrated by way of example.

The first memory block BLK1 includes a plurality of cell strings ST coupled between a source line SL and a first bit line BL1 through an n-th bit line BLn, where n is a positive integer. The cell strings ST are coupled in common to the source line SL. Among the cell strings ST, cell strings ST arranged along an X direction are coupled to the bit lines BL1 through BLn. Among the cell strings ST, cell strings ST arranged along a Y direction are coupled to any one of the bit lines BL1 through BLn.

The bit lines BL1 through BLn are electrically connected to page buffers PB1 through PBn, respectively. The page buffers PB1 through PBn are included in the page buffer group 140. For example, the first bit line BL1 is electrically connected to the first page buffer PB1, and the n-th bit line BLn is electrically connected to the n-th page buffer PBn.

Each of the cell strings ST includes a source select transistor SST, memory cells MC1 through MCi, where i is a positive integer, and a drain select transistor DST. A cell string ST coupled to the first bit line BL1, among the plurality of cell strings ST, is described by way of example.

The drain select transistor DST is disposed between the first bit line BL1 and the first memory cell MC1. The source select transistor SST is disposed between the i-th memory cell MCi and the source line SL. The memory cells MC1 through MCi are disposed between the drain select transistor DST and the source select transistor SST. The quantity of drain select transistors DST and the quantity of source select transistors SST are not limited to those illustrated in FIG. 3. In addition to the first to i-th memory cells MC1 through MCi, dummy cells may be disposed between the drain select transistor DST and the source select transistor SST. The memory cells MC1 through MCi store user data or normal data, and the dummy cells store dummy data.

Gates of drain select transistors DST included in different cell strings ST are coupled to a drain select line DSL. Gates of the memory cells MC1 through MCi included in different cell strings ST are coupled to word lines WL1 through WLi, respectively. Gates of source select transistors SST included in different cell strings ST are coupled to a source select line SSL. A group of memory cells included in cell strings ST arranged in the X direction and coupled to the same word line may be referred to as a page PG. In the memory device, a program operation or a read operation on a selected memory block may be performed on a page PG basis.

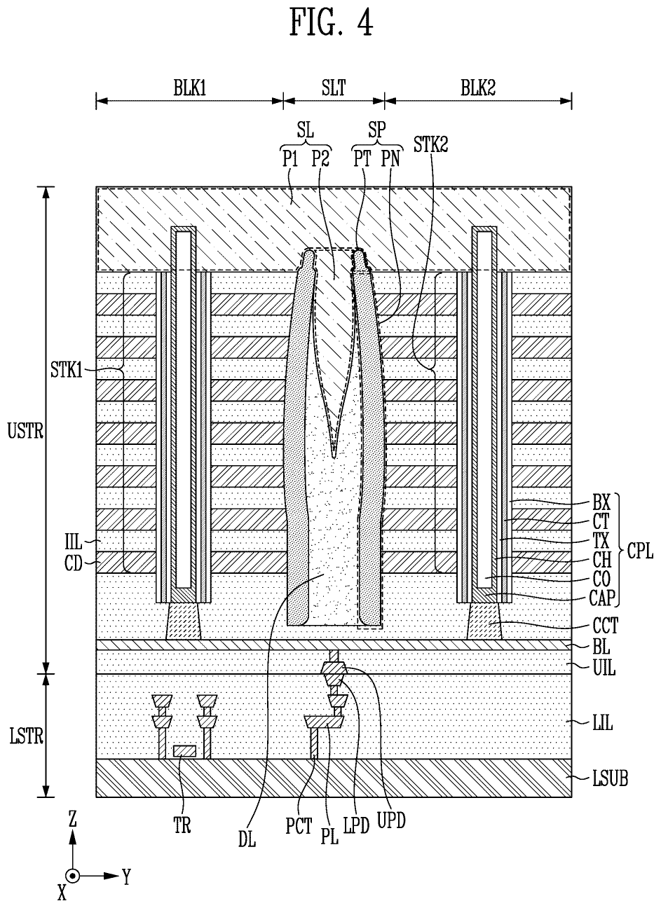

FIG. 4 is a view illustrating the cross-section of a memory device including a slit according to an embodiment of the present disclosure.

Referring to FIG. 4, a cross-section of the memory device 100 shown in FIG. 2 is illustrated by way of example. FIG. 4 illustrates a cross-section of a first memory block BLK1, a cross-section of a second memory block BLK2, a slit SLT between the first memory block BLK1 and the second memory block BLK2, a source line SL and a bit line BL coupled to the first memory block BLK1 and the second memory block BLK2, and a cross-section of a peripheral circuit, for example, peripheral circuit 180 of FIG. 2, disposed under the first memory block BLK1 and the second memory block BLK2.

The memory device 100 may include an upper structure USTR, a first structure, and a lower structure LSTR, a second structure. The upper structure USTR may be disposed on the lower structure LSTR. The upper structure USTR includes the first memory block BLK1 and the second memory block BLK2, the slit SLT, the source line SL, and the bit line BL. The source line SL is disposed on or above the first memory block BLK1 and the second memory block BLK2, and the bit line BL is disposed under or below the first memory block BLK1 and the second memory block BLK2. The lower structure LSTR includes the peripheral circuit, such as the peripheral circuit 180 of FIG. 2.

The first memory block BLK1 includes a first stacked body STK1, and the second memory block BLK2 includes a second stacked body STK2. The first stacked body STK1 is spaced apart from the second stacked body STK2 by the slit SLT. Each of the first stacked body STK1 and the second stacked body STK2 extend along the X direction. The slit SLT extends along the X direction between the first stacked body STK1 and the second stacked body STK2.

Each of the first stacked body STK1 and the second stacked body STK2 includes conductive layers CD alternately stacked with interlayer insulating layers IIL. The conductive layers CD and the interlayer insulating layers IIL are alternately stacked in a Z direction. Each of the conductive layers CD may be formed of at least one of tungsten (W), cobalt (Co), nickel (Ni), molybdenum (Mo), silicon (Si), or polysilicon (Poly-Si). The conductive layers CD correspond to the drain select line DSL, the word lines WL1 through WLi, and the source select line SSL of FIG. 3. Each of the interlayer insulating layers IIL may be formed of an oxide layer, for example, a silicon oxide layer.

Each of the first memory block BLK1 and the second memory block BLK2 include a plurality of cell plugs CPL. The cell plugs CPL extend through the first stacked body STK1 and the second stacked body STK2. Each of the cell plugs CPL extend in the Z direction. The cell plugs CPL correspond to the cell strings ST of FIG. 3. The memory cells MC1 through MCi of FIG. 3 are formed at locations where the cell plugs CPL and the conductive layers CD intersect.

Each of the cell plugs CPL includes a cylindrical blocking layer BX formed along an inner wall of a stacked body, a charge trap layer CT formed along the inner wall of the blocking layer BX, a tunnel isolation layer TX formed along the inner wall of the charge trap layer CT, a channel layer CH formed along the inner wall of the tunnel isolation layer TX, a core pillar CO formed in a cylindrical shape in an area enclosed or surrounded by the channel layer CH, and a capping layer CAP coupled to the channel layer CH under one end of the core pillar CO. The blocking layer BX and the tunnel isolation layer TX may be formed of an oxide layer (for example, a silicon oxide layer), an oxynitride layer (for example, a silicon oxynitride layer), or a combination thereof. The charge trap layer CT may include a nitride layer or a variable resistance material. Each of the channel layer CH and the capping layer CAP may be formed of a doped silicon layer. The core pillar CO may be formed of an insulating layer or a conductive layer. The blocking layer BX, the charge trap layer CT, the tunnel isolation layer TX, the channel layer CH, and the core pillar CO, which are included in each cell plug CPL, extend in a vertical direction with respect to the drawing, or the Z direction. The blocking layer BX, the charge trap layer CT, the tunnel isolation layer TX, the channel layer CH, and the core pillar CO may be concentrically formed.

The blocking layer BX, the charge trap layer CT, and the tunnel isolation layer TX, which are included in each of the cell plugs CPL, do not protrude farther than the first stacked body STK1 and the second stacked body STK2 in the Z direction in the example of FIG. 4. The channel layer CH included in each of the cell plugs CPL protrudes further than the first stacked body STK1 and the second stacked body STK2 in the Z direction in the example of FIG. 4. The channel layer CH included in each of the cell plugs CPL contacts the source line SL in the example of FIG. 4.

The slit SLT may be disposed between the first stacked body STK1 and the second stacked body STK2. The slit SLT electrically separates the first stacked body STK1 from the second stacked body STK2. For example, the slit SLT facilitates operation of the first stacked body STK1 as a different memory block from the second stacked body STK2. The width of the slit SLT in a horizontal or Y direction may become smaller toward a top end of the slit SLT, such as the uppermost end of the slit in the Z direction, such as shown in FIG. 4. The slit SLT is filled with portions of spacers SP, a dummy layer DL, and the source line SL. Each of the spacers SP may be formed along a periphery of the slit SLT, which periphery is adjacent to one of the first stacked body STK1 and the second stacked body STK2. A gap between the spacers SP may become narrower toward the top end of the slit SLT, such as the uppermost end of the slit in the Z direction.

The dummy layer DL fills a portion of the slit SLT. The dummy layer DL fills a part of the slit SLT between the spacers SP. The dummy layer DL includes a recess that is open at the top end of the slit SLT, such as the uppermost end of the slit in the Z direction. The width of the recess within the dummy layer DL may be formed in various manners. For example, the width of the recess of the dummy layer DL may increase and then decrease as the recess extends in the Z direction. For example, a width of an upper portion or top end of the recess of the dummy layer DL may widen as the recess extends from the top end toward a lowermost end or bottom of the recess. A width of a lower portion or bottom end of the recess of the dummy layer DL narrows as the recess extends in the Z direction from a top end of the lower portion toward the bottom of the recess. For example, the width of the recess of the dummy layer DL may narrow as the recess extends in the Z direction from a top end of the recess toward the bottom of the recess. For example, the width of the recess of the dummy layer DL may be uniform regardless of the height of the dummy layer DL. The dummy layer DL may have various shapes.

Each of the spacers SP has a penetrating portion PN and a protruding portion PT. A penetrating portion PN of a first spacer SP is disposed between the first stacked body STK1 and the dummy layer DL, and a penetrating portion PN of a second spacer SP is disposed between the second stacked body STK2 and the dummy layer DL. The protruding portions PT of the spacers SP protrude beyond or away from the first stacked body STK1 and the second stacked body STK2 in an upward or Z direction. In the present disclosure, the penetrating portion PN and the protruding portion PT are shown as separate elements for convenience of description and may be physically coupled together or may be formed as a single, unified component. Thus, an interface between the penetrating portion PN and the protruding portion PT may not be observable.

The penetrating portions PN of the spacers SP are formed along the outer periphery of the slit SLT. The penetrating portion PN of the first spacer contacts the first stacked body STK1, and the penetrating portion PN of the second spacer contacts the second stacked body STK2. The penetrating portions PN of the spacers SP contact the side surfaces of the conductive layers CD and the interlayer insulating layers IIL of the stacked bodies STK1 and STK2, which are exposed by the slit SLT.

The protruding portion PT of each of the spacers SP extends from the corresponding penetrating portion PN. The protruding portion PT extends from the corresponding penetrating portion PN in an upward or Z direction. Each of the top surfaces of the protruding portions PT of the spacers SP may include one or more curved surfaces. The top of the cross section of each of the protruding portions PT of spacers SP may include a curved line. The tops of the protruding portions PT of the spacers SP may have a symmetrical curved surface shape or an asymmetrical curved surface shape.

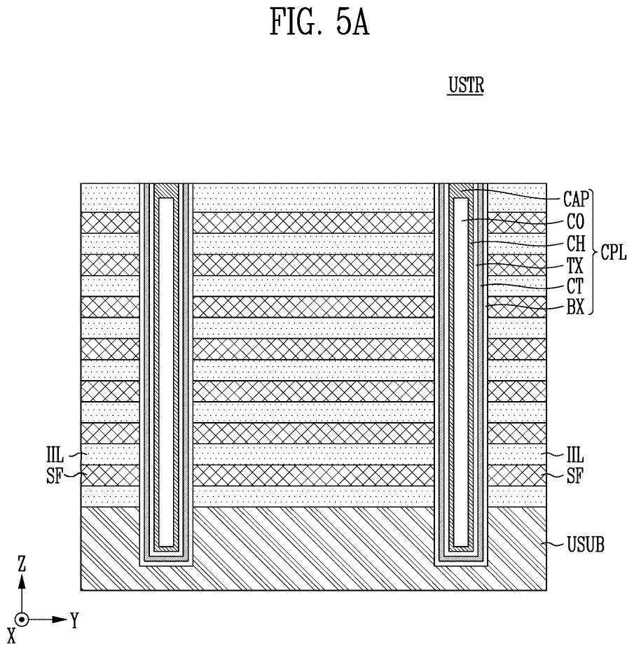

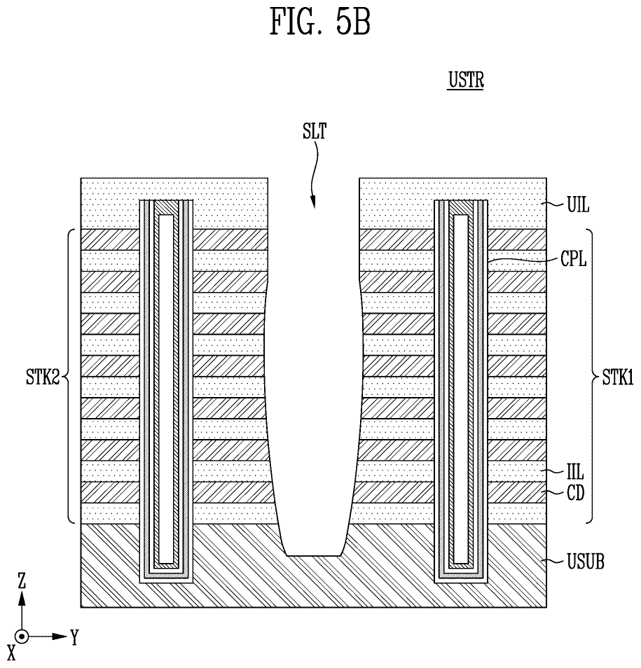

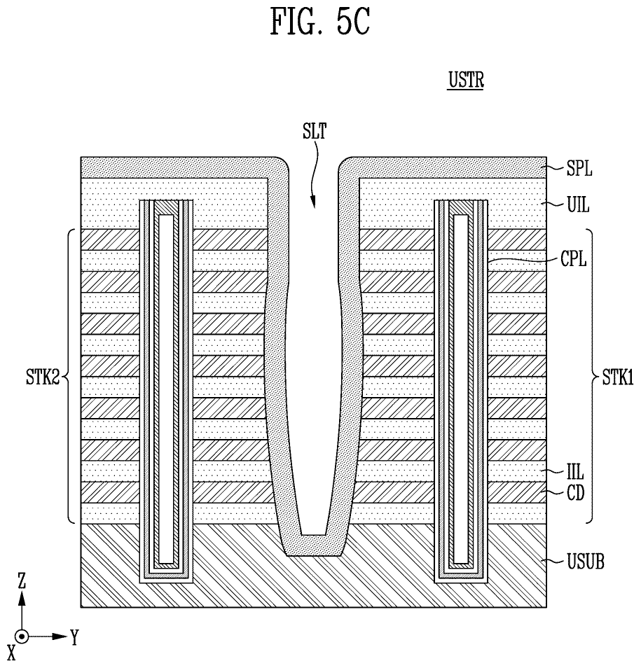

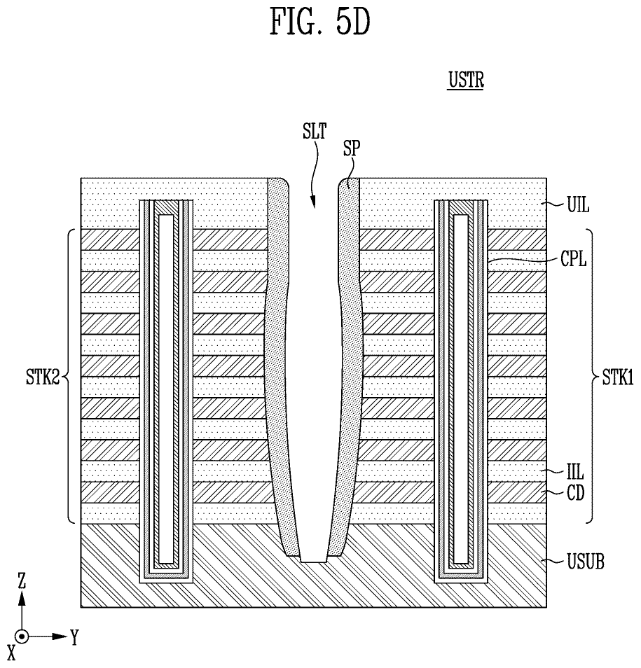

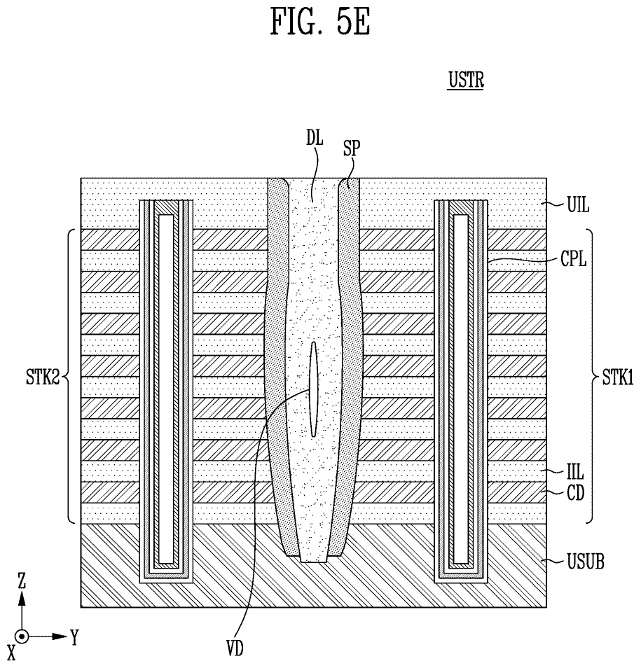

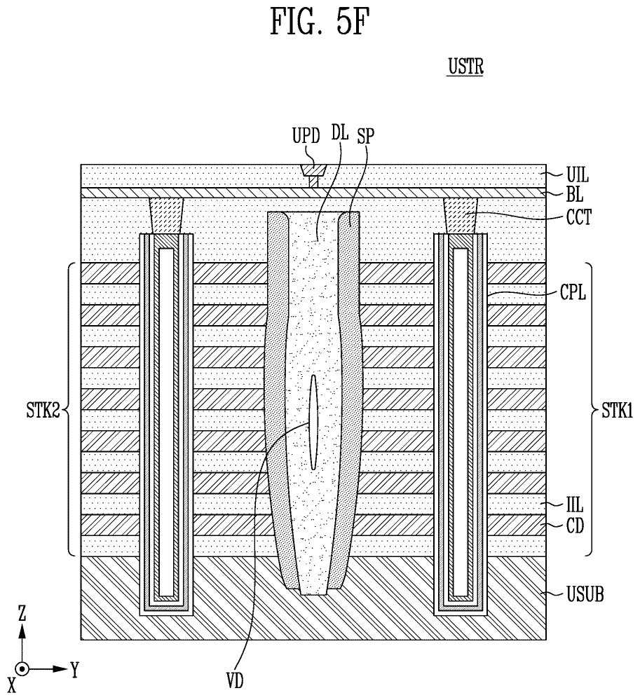

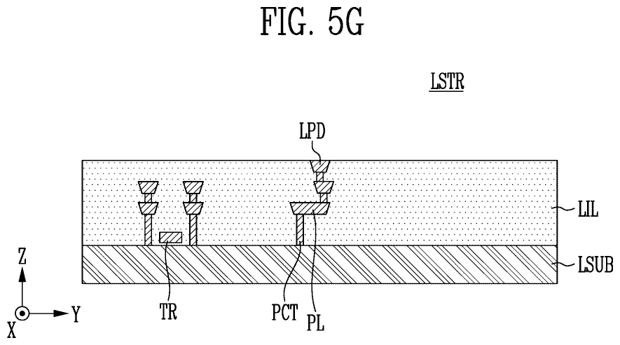

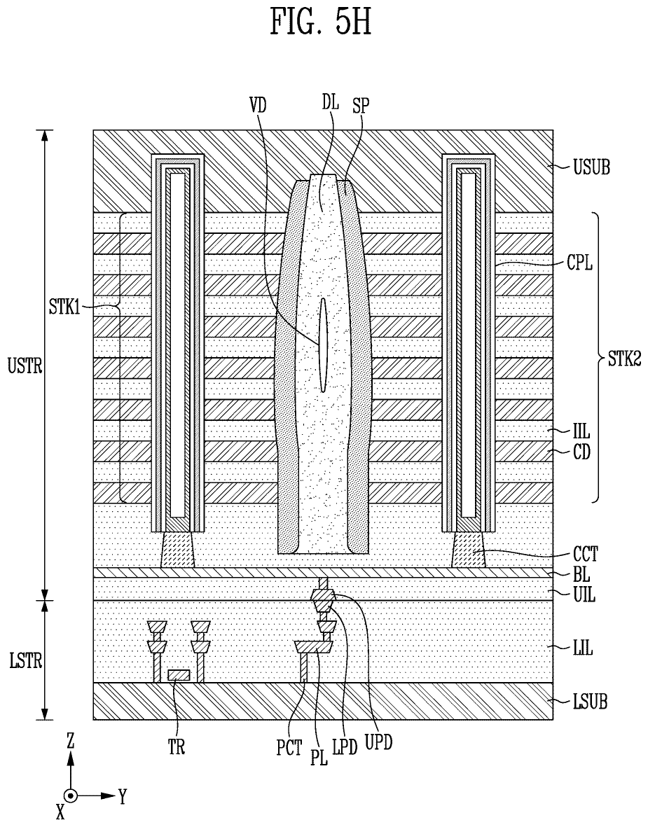

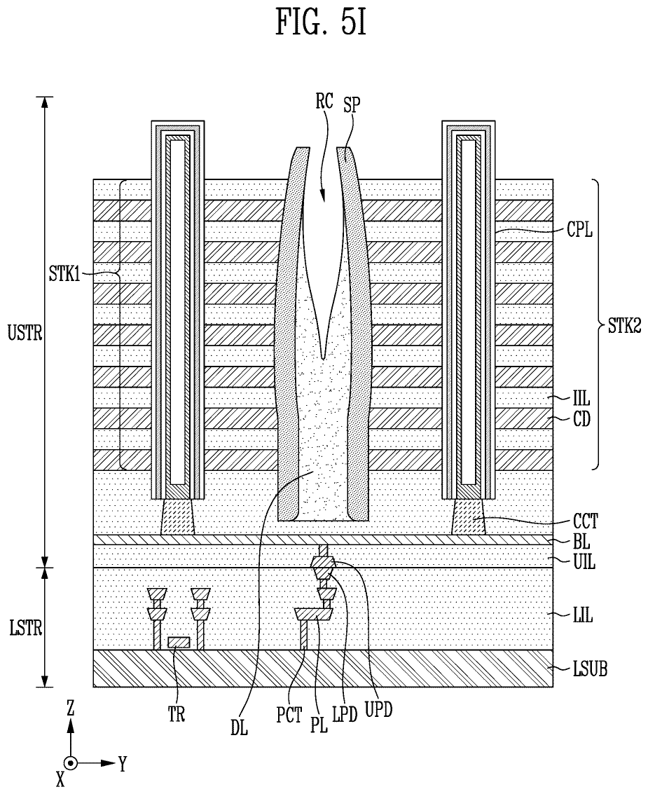

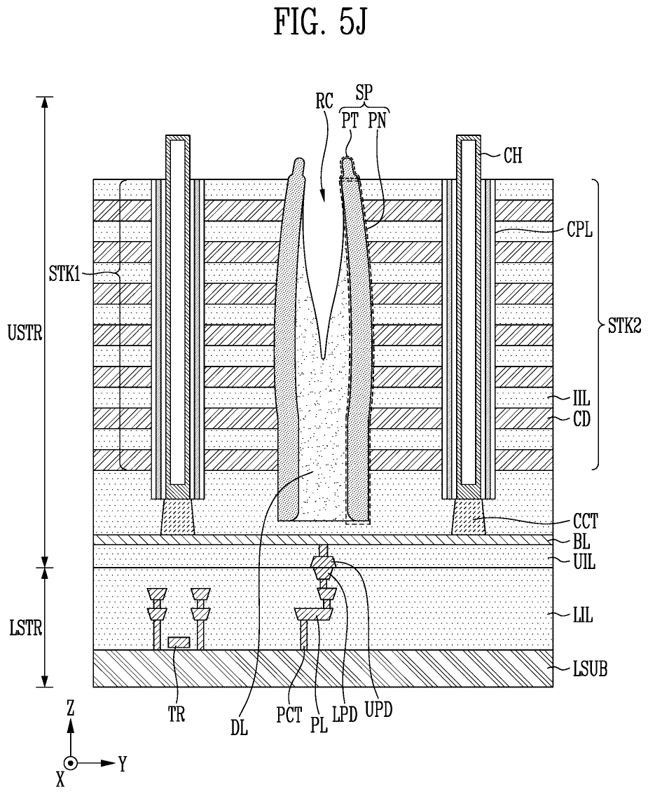

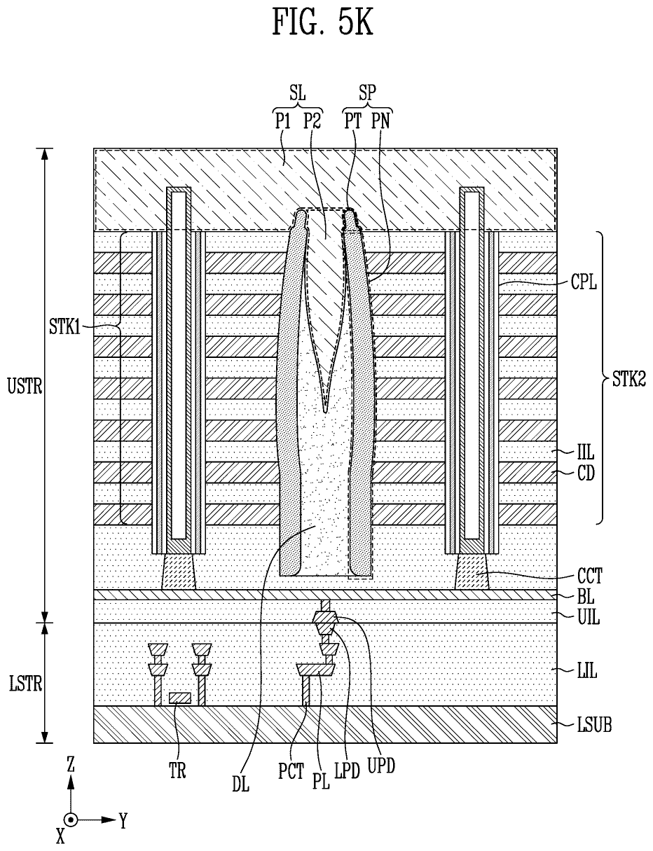

The horizontal width of the protruding portion PT may be smaller than the horizontal width of the penetrating portion PN of the spacers SP. For example, the width of a part of the protruding portion PT in the Y direction may be smaller than the horizontal width of the penetrating portion PN. The shapes of the cross sections of the spacers SP is described in detail with reference to FIG. 5J.

The source line SL is disposed over the first stacked body STK1 and the second stacked body STK2, the dummy layer DL, and the spacers SP. The source line SL includes a first portion P1, disposed on the stacked bodies STK1 and STK2 and the slit SLT, and a second portion P2 disposed inside the slit SLT. The first portion P1 and the second portion P2 of the source line SL contact each other. In the present disclosure, although the first portion P1 and the second portion P2 are shown as separate elements for convenience of description, the first portion P1 and the second portion P2 may be formed as a single component comprising the same material. Thus, an interface between the first portion P1 and the second portion P2 may not be observable.

The first portion P1 of the source line SL extends or is disposed in the Z direction on or above the stacked bodies STK1 and STK2. The first portion P1 of the source line SL is coupled to or directly contacts the channel layer CH of each of the cell plugs CPL. The first portion P1 of the source line SL is disposed above the slit SLT in the Z direction in the example of FIG. 4.

The second portion P2 of the source line SL extends from the first portion P1 of the source line SL to fill the slit SLT. The second portion P2 of the source line SL is disposed between the spacers SP. For example, the second portion P2 fills at least part of a region between the penetrating portions PN and at least part of a region between the protruding portions PT.

The second portion P2 of the source line SL fills the recess of the dummy layer DL and contacts the dummy layer DL. A lower surface of the second portion P2 of the source line SL directly contacts the top or upper surface of the dummy layer DL. The horizontal width (width in the Y direction) of a part of the second portion P2 of the source line SL narrows as the second portion P2 extends toward the bottom of the recess of the dummy layer DL. For example, the part of the second portion P2 of the source line SL, which contacts the dummy layer DL, has a width that narrows as the second portion P2 extends in a direction toward the bottom of the recess of the dummy layer DL.

The source line SL encloses or surrounds the protruding portions PT of the spacers SP. For example, one surface of each protruding portion PT contacts the first portion P1 of the source line SL, and the other surface of the protruding portion PT contacts the second portion P2 of the source line SL.

According to an embodiment of the present disclosure, the dummy layer DL and the source line SL are made of a similar material. The dummy layer DL and the source line SL may be made of polysilicon. For example, each of the dummy layer DL and the source line SL may include a silicon layer doped with impurities or an undoped silicon layer. The impurities may include a Group 13 element (for example, boron, aluminum, gallium, or indium) or a Group 15 element (for example, phosphorus, arsenic, or antimony). The undoped silicon layer may be a silicon layer undoped with impurities. For example, the dummy layer DL and the source line SL may both be formed of polysilicon doped with the same type of impurities. In an embodiment, the dummy layer DL may contain materials slightly different from the materials of the source line SL. For example, the dummy layer DL may be formed of undoped polysilicon, and the source line SL may be formed of polysilicon doped with impurities. The dummy layer DL and the source line SL may be formed of various combinations of materials.

In the example where the dummy layer DL and the source line SL are made of the same type of material, a coupling force between the dummy layer DL and the source line SL may be improved compared to the example where the dummy layer DL and source line SL are formed of different types of materials. When the dummy layer DL and the source line SL contain the same material, the source line SL may be adhered to the dummy layer DL. In an embodiment, laser annealing may be performed on the interface between the dummy layer DL and the source line SL. When laser annealing is performed on the interface between the dummy layer DL and the source line SL, an alloy may be formed on the interface, thus further improving an adhesive strength between the dummy layer DL and the source line SL.

As the coupling force between the dummy layer DL and the source line SL increases, the strength of the memory device 100 may increase, and bending of the memory device 100 may decrease. Thus, according to the present disclosure, the source line SL is strongly coupled to the dummy layer DL filling the slit SLT, thereby improving the physical strength, such as the ability to resist fracture, deformation, or failure under applied load or force, of the memory device 100.

According to the present disclosure, the second portion P2 of the source line SL extends into an area or space between the spacers SP and may fill the recess of the dummy layer DL. Because the gap between the spacers SP narrows as the gap extends in the Z direction, the coupling force between the source line SL and the stacked bodies STK1 and STK2 may be further improved when the space between the spacers SP is filled with the source line SL. Therefore, the physical strength of the memory device 100 may further increase.

Referring to FIG. 4, the bit lines BL are disposed under the first stacked body STK1 and the second stacked body STK2. The bit line BL is formed over an upper insulating layer UIL. The bit line BL is coupled in common with the cell plug CPL of the first memory block BLK1 and the cell plug CPL of the second memory block BLK2. The bit line BL is coupled to the cell plugs CPL through cell contacts CCT. The cell contacts CCT contact at least one of the channel layers CH or capping layers CAP of the cell plugs CPL.

The upper structure USTR includes an upper pad UPD exposed through the bottom surface of the upper structure USTR. The lower structure LSTR includes a lower pad LPD exposed through the top surface of the lower structure LSTR. When the upper structure USTR is stacked over the lower structure LSTR, the upper pad UPD contacts and is electrically connected to the lower pad LPD. Each of the upper pad UPD and the lower pad LPD contains a conductive material. The bit line BL is coupled to the peripheral circuit, for example, the peripheral circuit 180 of FIG. 2, through the upper pad UPD and the lower pad LPD.

The lower structure LSTR includes a lower substrate LSUB and a peripheral circuit, for example, the peripheral circuit 180 of FIG. 2, over the lower substrate LSUB. For example, the peripheral circuit may include a transistor TR, a peripheral contact plug PCT, and a peripheral line PL. The transistor TR, the peripheral contact plug PCT, and the peripheral line PL may have various patterns or configurations depending on the peripheral circuit. For example, the quantities or arrangement of transistors TR, peripheral contact plugs PCT, and peripheral lines PL may be modified in various forms. A lower insulating layer LIL may be disposed between the transistor TR, the peripheral contact plug PCT, and the peripheral line PL. For example, the transistor TR, the peripheral contact plug PCT, and the peripheral line PL are formed in the lower insulating layer LIL.

FIG. 5A through FIG. 5K are views of a semiconductor device formed utilizing a method of manufacturing a memory device including a slit according to an embodiment of the present disclosure.

Referring to FIG. 5A, an upper structure USTR includes a plurality of first material layers IIL alternately stacked with a plurality of second material layers SF over an upper substrate USUB. Each of the first material layers IIL is formed of an insulating material. For example, each of the first material layers IIL may be formed of an oxide layer (for example, a silicon oxide layer). The second material layers SF may be formed of a material that are selectively removed in a subsequent process. The second material layers SF may be advantageously formed of a material having an etch selectivity different from the etch selectivity of the first material layers IIL. For example, each of the second material layers SF may be formed of a nitride layer.

Cell plugs CPL may be formed in the upper structure USTR. The cell plugs CPL penetrate or extend through the first material layers IIL and the second material layers SF of the upper structure USTR. Each of the cell plugs CPL extends in the Z direction. The cell plugs CPL may be arranged along the X direction and the Y direction. A shape of a cross-section of the cell plugs CPL in the X-Y plane may be circular, elliptical, rectangular, triangular, and so forth. A lower portion of each of the cell plugs CPL is disposed inside the upper substrate USUB. Descriptions of components BX, CT, TX, CH, CO, and CAP included in each of the cell plugs CPL are made with reference to FIG. 4.

Referring to FIG. 5B, an upper insulating layer UIL is formed over the upper structure USTR. The upper insulating layer UIL encloses the cell plugs CPL such that the upper portions of the cell plugs CPL are not exposed. The upper insulating layer UIL covers the top surfaces of the cell plugs CPL. The upper insulating layer UIL may include an oxide layer. As shown in FIG. 5B, the upper insulating layer UIL advantageously includes a first material layer IIL that is an uppermost material layer among the plurality of first material layers IIL of FIG. 5A.

A slit SLT passing through the upper structure USTR is formed. The slit SLT extends in the Z direction. Sections of the first material layers IIL and the second material layers SF may be etched to form the slit SLT. In order to form the slit SLT at a specific position or location, an anisotropic dry etching process may be performed. The slit SLT extends along the X direction. The slit separates or divides the upper structure USTR into two stacked bodies, a first stacked body STK1 and a second stacked body STK2, spaced apart from each other in the Y direction.

The width of the slit SLT may be formed differently depending on the depth of the slit SLT. For example, the slit SLT may have one or more tapered cross sections. In an example, the horizontal width (for example, the width in the Y direction) of the slit SLT may vary along the Z direction, including narrower and wider sections.

The slit SLT exposes a portion of the upper substrate USUB. While the slit SLT is formed, a portion of the top surface of the upper substrate USUB is etched. As a result, the level of the bottom surface of the slit SLT may be lower than the level of the top surface of the upper substrate USUB in the Z direction.

The plurality of second material layers SF are replaced with a plurality of third material layers CD through the slit SLT. The third material layers CD are conductive layers. For example, each of the third material layers CD may be formed of at least one of tungsten (W), cobalt (Co), nickel (Ni), molybdenum (Mo), silicon (Si), and polysilicon (Poly-Si). The third material layers CD may be used as gate lines, for example, a drain select line DSL, word lines WL, and a source select line SSL.

The upper structure USTR includes the first stacked body STK1 spaced apart from the second stacked body in the Y direction. The first stacked body STK1 and the second stacked body STK2 are separated from each other by the slit SLT. The third material layers CD included in the first stacked body STK1 are insulated from the third material layers CD included in the second stacked body STK2. The third material layers CD included in the first stacked body STK1 enclose or surround the cell plug CPL extending through the first stacked body STK1. The third material layers CD included in the second stacked body STK2 enclose or surround the cell plug CPL extending through the second stacked body STKs.

Referring to FIG. 5C, a spacer layer SPL is formed on the upper structure USTR. The spacer layer SPL conforms to the shape of the upper or exposed surfaces of the first stacked body STK1 and the second stacked body STK2, including the periphery of the slit SLT. The spacer layer SPL are formed on the top surfaces of the first stacked body STK1 and the second stacked body STK2. The spacer layer SPL is formed along the walls of the first stacked body STK1 and the second stacked body STK2 along the outer periphery of the slit SLT. The spacer layer SPL may contain an insulating material (for example, an oxide layer, a nitride layer, and so forth). A deposition process or the like may be performed to form the spacer layer SPL on the upper structure USTR at a predetermined thickness.

Referring to FIG. 5D, a portion of the spacer layer SPL is removed, forming the spacers SP. For example, the section of the spacer layer SPL disposed on the upper or topmost surfaces of the first stacked body STK1 and the second stacked body STK2 is removed. A portion of the spacer layer SPL disposed along the bottom periphery of the slit SLT is removed by extending the slit into the upper substrate USUB. As a result, the spacers SP are disposed on the outer periphery of the slit SLT and along the sides of the first stacked body STK1 and the second stacked body STK2. The operation performed to result in the cross section shown in FIG. 5D may be referred to as spacer etch-back.

The cross section of the spacers SP may each have a curved corner. For example, the top corners of the spacers SP, exposed through the slit SLT, may be formed having curved surfaces.

While the section of the spacer layer SPL is removed, the upper substrate USUB may be further etched, resulting in a slit SLT that extends further into the upper substrate USUB than prior to the removal. The depth of the slit SLT in the upper substrate USUB is increased beyond the depth of the slit SLT before the lower section of the spacer layer SPL is removed.

Referring to FIG. 5E, the slit SLT in which the spacers SP are formed is filled with a dummy layer DL. The dummy layer DL may contain polysilicon. Because polysilicon corresponds to a material having good step coverage characteristics, the dummy layer DL better fills the slit SLT than a material having bad step coverage characteristics.

In some embodiments, a void VD may form in the dummy layer DL. A void VD refers to an empty space occurring when the dummy layer DL does not completely fill the slit SLT. Because the shape of the slit SLT is shorter in length in the Y-direction length than a length in the Z-direction length, one or more voids VD may be formed in the dummy layer DL.

When spacer etch-back is performed, described in relation to FIG. 5D, the quantity and/or volume of voids VD occurring may be reduced compared to when spacer etch-back is not performed. A space to be filled with the dummy layer DL may be widened to accommodate the spacer etch-back process. Alternatively, when the spacers SP have curved corners, as shown in FIG. 5D, the width of the top of the slit SLT increases, thus making filling of the slit SLT with the dummy layer DL easier. Therefore, according to the present disclosure, the voids VD formed in the dummy layer DL may be reduced or eliminated.

Referring to FIG. 5F, cell contacts CCT, a bit line BL, and an upper pad UPD are formed over the upper structure USTR. The bit line BL is coupled to the cell plugs CPL through corresponding cell contacts CCT. The upper pad UPD is exposed through the top surface of the upper structure USTR. Each of the cell contacts CCT, the bit line BL, and the upper pad UPD contains a conductive material.

Referring to FIG. 5G, a lower structure LSTR is formed. The lower structure LSTR includes a lower substrate LSUB, a lower insulating layer LIL disposed over the lower substrate LSUB, and a peripheral circuit, for example, the peripheral circuit 180 of FIG. 2, formed in the lower insulating layer LIL. The peripheral circuit includes a transistor TR, a peripheral contact plug PCT, and a peripheral line PL. The lower structure LSTR includes a lower pad LPD exposed through the top surface of the lower structure LSTR. Each of the peripheral contact plug PCT, the peripheral line PL, and the lower pad UPD contains a conductive material.

Referring to FIG. 5H, the upper structure USTR may optionally be turned upside-down. FIG. 5H through FIG. 5K are described with the presumption that the structure USTR is turned upside-down for convenience of description. The upper structure USTR is stacked over the lower structure LSTR. The upper substrate USUB is located in an upper portion of an upside-down upper structure USTR relative to the drawing. The upper pad UPD is exposed through the bottom surface of the upside-down upper structure USTR. The upside-down upper structure USTR is stacked over the lower structure LSTR such that the upper pad UPD contacts the lower pad LPD of the lower structure LSTR.

Referring to FIG. 5I, the upper substrate USUB is removed. A portion of the dummy layer DL is removed from an upper end of the slit, thereby forming a recess RC in the dummy layer DL. The recess may be formed while the upper substrate USUB is removed. For example, when the dummy layer DL contains polysilicon, the dummy layer DL may be etched together with the upper substrate USUB using etchant that etches the upper substrate USUB. Alternatively, after the upper substrate USUB is etched, the dummy layer DL may be etched using a separate etchant. The recess RC of the dummy layer DL refers to an empty space formed when a portion of the dummy layer DL filling the slit SLT is removed. The recess RC of the dummy layer DL is formed with an opening at a first end of the slit SLT. The slit SLT has a first end and a second end, where the first end is disposed opposite to the second end, and the second end is disposed closer to the lower substrate LSTR than the first end. The width of a lower portion of the recess RC of the dummy layer DL may narrow as the recess extends toward the second end.

In some embodiments, when a void VD is formed inside the dummy layer DL, the void VD may be removed when the recess RC is formed. For example, the void VD may be exposed while a portion of the dummy layer DL is removed to form the recess RC. Alternatively, when a portion of the dummy layer DL is removed, a recess RC including a region where the void VD is located may be formed. As a result, when the recess RC is formed in the dummy layer DL, one or more voids VD included in the dummy layer DL may be removed.

Unlike the example illustrated in FIG. 5I, a void VD may not be removed when the recess RC is formed in the dummy layer DL. For example, a void VD may not be exposed while a portion of the dummy layer DL is removed, such as when one or more voids VD are formed in a section of the dummy layer DL that is not removed. For example, a top surface of the void VD may be located lower than the bottom surface of the recess RC of the dummy layer DL. When the void VD is not exposed by the recess RC of the dummy layer DL, the shape of the recess RC may be formed differently that the shape of FIG. 5I. For example, the horizontal width of the recess RC may not vary with or along the height of the recess RC. For example, the horizontal width of the recess RC may widen as the recess RC extends toward the second end or bottom of the slit SLT. The dummy layer DL and the recess RC may be formed having various shapes.

As the upper substrate USUB is removed, upper portions of cell plugs CPL are exposed. For example, portions of the cell plugs CPL, located inside the upper substrate USUB as shown in FIG. 5A are exposed to the outside of the memory device 100 as the upper substrate USUB is etched as shown in FIG. 5I. As the upper substrate USUB is removed and a portion of the dummy layer DL is removed, upper portions of the spacers SP at the first end of the slit SLT are exposed. For example, portions of the spacers SP disposed between the upper substrate USUB and the dummy layer DL as shown in FIG. 5E are exposed to the outside of the memory device 100 as the upper substrate USUB and the dummy layer DL are etched as shown in FIG. 5I.

The area of exposed surfaces of the spacers SP may vary with the direction. For example, a side surface facing the inside of the slit SLT may have more exposed area than a side surface facing away from the slit SLT. A side surface facing away from the slit SLT is referred to as an “outer side surface,” and a side surface facing the inside of the slit SLT is referred to as an “inner side surface” of a spacer SP. The spacer SP adjacent to the first stacked body STK1 is referred to as the left spacer SP, and the spacer SP adjacent to the second stacked body STK2 is referred to as the right spacer in FIG. 5I. The inner side surface, or the left side surface, of the right spacer SP is exposed further down than the outer side surface, or the right side surface, of the right spacer SP is exposed, and the inner side surface, or the right side surface, of the left spacer SP is exposed further down than the outer side surface, or the left side surface, of the left spacer SP is exposed.

Unlike the structure illustrated in FIG. 5I, an embodiment in which the inner side surface of each spacer SP is less exposed than the outer side surface of the spacer SP is exposed, or an embodiment in which the outer side surface and the inner side surface of each spacer SP are equally exposed may also be implemented. The more the dummy layer DL is etched, the lower the recess RC is positioned within the slit SLT, the more the inner side surface of each spacer SP is exposed.

Referring to FIG. 5J, the channel layer CH of each of the cell plugs CPL is exposed. Exposed portions of the cell plugs CPL are removed until the channel layers CH are exposed. Regions of the blocking layer BX, the charge trap layer CT, and the tunnel isolation layer TX included in each of the cell plugs CPL and protruding outside the first stacked body STK1 and the second stacked body STK2 are removed. The channel layer CH included in each of the cell plugs CPL is exposed, where the channel layer CH protrudes further upward in the Z direction than the first stacked body STK1 and the second stacked body STK2 extend in the Z direction. Thus, the channel layer CH extends beyond or above the first stacked body STK1 and the second stacked body STK2.

The protruding portions PT of the spacers SP are etched as shown in FIG. 5I. The spacers SP may be etched while portions of the cell plugs CPL are removed. By using etchant for etching the blocking layer BX, the charge trap layer CT, and the tunnel isolation layer TX, the protruding portions PT of the spacers SP, exposed to the outside of the memory device 100, may be etched. For example, the surfaces of the spacers SP not covered by the first stacked body STK1 and the second stacked body STK2 or the dummy layer DL are etched. Compared to the spacers SP shown in FIG. 5I, the volume of the spacers SP is reduced as shown in FIG. 5J.

Because the top surfaces of the spacers SP are etched, the lengths of the spacers SP in the Z direction are reduced. In addition, the tops of the spacers SP may be rounded, whereby each of the top surfaces of the spacers SP includes a curved surface. The width of the exposed portion of each spacer SP is reduced due to the etching. For example, the horizontal width of each protruding portion PT of a spacer SP is narrower than the horizontal width of the corresponding penetrating portion PN of the spacer SP.

The etched areas of the inner side surfaces may be different from the etched area of the outer side surfaces of the spacer SP. For example, the outer side surface of each spacer SP may be etched to form a first shape, and the inner side surface of each spacer SP may be etched to form a second shape different from the first shape.

The position of the recess RC of the dummy layer DL affect the shape of the cross section of each spacer SP. The inner side surface of each spacer SP may include a lower region that is covered by the dummy layer DL and is not etched, and an upper region that is not covered by the dummy layer DL and is etched. Depending on the position of the upper end of the recess RC of the dummy layer DL, the curved surface shape of the inner side surface of each spacer SP may vary.

Referring to FIG. 5K, a source line SL is formed over the upper structure USTR. The source line SL covers the first stacked body STK1 and the second stacked body STK2, the spacers SP, and the dummy layer DL. The source line SL includes a first portion P1 disposed on the stacked bodies STK1 and STK2 and above the slit SLT and a second portion P2 disposed inside the slit SLT. The second portion P2 of the source line SL advantageously fills the recess RC of the dummy layer DL. The second portion P2 of the source line SL contacts the dummy layer DL. The source line SL is formed to enclose or surround the previously exposed upper portion of each spacer SP as shown in FIG. 5J. The source line SL encloses or surrounds each protruding portion PT of the spacers SP. The source line SL contacts a part of each penetrating portion PN of the spacers SP. The first portion P1 and the second portion P2 of the source line SL are advantageously formed as a single component comprising the same material.

After the source line SL is formed, a laser annealing process may be performed on an interface between the dummy layer DL and the source line SL. Laser annealing refers to a process of applying heat at a predetermined temperature or higher to material (for example, polysilicon) contained in the dummy layer DL and the source line SL. When laser annealing is performed on the interface between the dummy layer DL and the source line SL, an alloy may be formed on the interface, thus improving adhesive strength between the dummy layer DL and the source line SL. In an embodiment, when the depth of the recess RC is less than or equal to a predetermined threshold (for example, 4000 Å), the laser annealing process is performed.

Because most voids VD formed in the dummy layer DL may be removed when the recess RC is formed, the recess RC is filled with the source line SL, and the coupling force between the dummy layer DL and the source line SL may be improved compared to that of a conventional structure. Therefore, according to the present disclosure, the strength of the memory device 100 may be improved, and bending of the memory device 100 may be reduced.

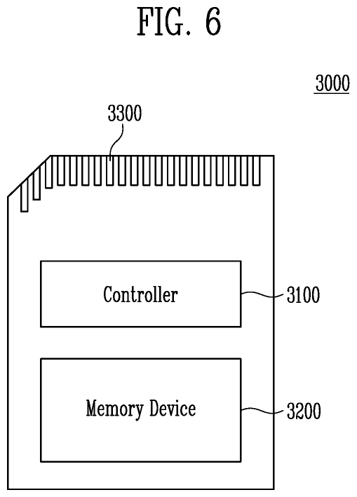

FIG. 6 is a diagram illustrating an embodiment of a memory card system including a memory device according to an embodiment of the present disclosure.

Referring to FIG. 6, a memory card system 3000 includes a controller 3100, a memory device 3200, and a connector 3300.

The controller 3100 is coupled to the memory device 3200. The controller 3100 accesses the memory device 3200. For example, the controller 3100 is configured to control a program operation, a read operation, an erase operation of the memory device 3200 and a background operation of the memory device 3200. The controller 3100 is configured to provide an interface between the memory device 3200 and a host. The controller 3100 runs firmware that controls the memory device 3200. For example, the controller 3100 may include components such as a random access memory (RAM), a processor, a host interface, a memory interface, and an error corrector.

The controller 3100 communicates with an external device through the connector 3300. The controller 3100 communicates with an external device, for example, a host, based on a specific communication protocol standard. For example, the controller 3100 may be configured to communicate with the external device through at least one of various communication protocol standards such as universal serial bus (USB), multimedia card (MMC), embedded MMC (eMMC), peripheral component interconnection (PCI), PCI-express (PCI-E), advanced technology attachment (ATA) protocol, serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe). For example, the connector 3300 may be configured according to at least one of the above-communication protocol standards.

The memory device 3200 includes a plurality of memory cells configured, for example, in the same manner as the memory device 100 illustrated in FIG. 1 and is formed utilizing the method of manufacturing a memory device according to the method described above with reference to FIG. 5A through FIG. 5K, including coupling material disposed inside a slit to a source line.

The controller 3100 and the memory device 3200 are integrated into a single semiconductor device to form a memory card. For example, the controller 3100 and the memory device 3200 may be integrated into a single semiconductor device, and may form a memory card such as a personal computer memory card international association (PCMCIA) card, a compact flash card (CF), a smart media card (SM or SMC), a memory stick, a multimedia card (MMC, RS-MMC, MMCmicro or eMMC), an SD card (SD, miniSD, microSD, or SDHC), or a universal flash storage (UFS).

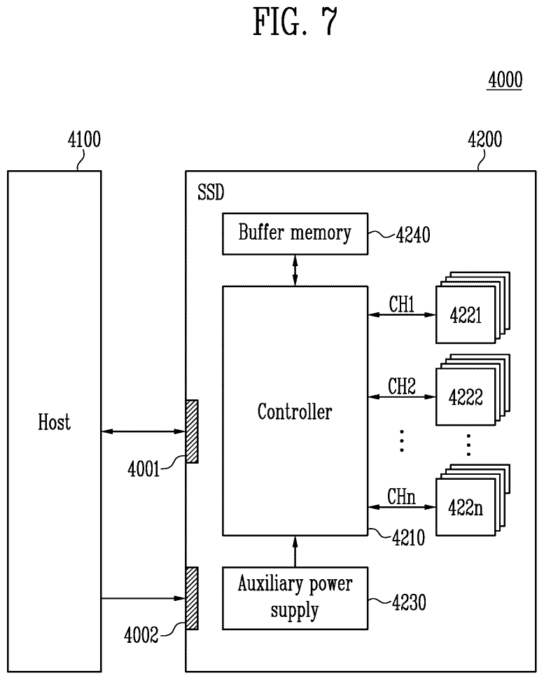

FIG. 7 is a diagram illustrating an embodiment of a solid state drive (SSD) system including a plurality of memory devices according to the present disclosure.

Referring to FIG. 7, an SSD system 4000 includes a host 4100 and an SSD 4200. The SSD 4200 exchanges signals with the host 4100 through a signal connector 4001 and receives power through a power connector 4002. The SSD 4200 includes a controller 4210, a plurality of memory devices 4221 through 422n, an auxiliary power supply 4230, and a buffer memory 4240.

The controller 4210 controls the plurality of memory devices 4221 to 422n in response to signals received from the host 4100. For example, the received signals may be signals based on the interfaces of the host 4100 and the SSD 4200. For example, the signals may be configured or constructed according to at least one of a plurality of interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

Each of the plurality of memory devices 4221 to 422n includes a plurality of memory cells configured to store data. Each of the plurality of memory devices 4221 through 422n is configured, for example, in the same manner as the memory device 100 illustrated in FIG. 1 and is formed utilizing the method of manufacturing a memory device according to the method described above with reference to FIG. 5A through FIG. 5K, including coupling material disposed inside a slit to a source line. The plurality of memory devices 4221 to 422n communicates with the controller 4210 through channels CH1 through CHn.

The auxiliary power supply 4230 is coupled to the host 4100 through the power connector 4002. The auxiliary power supply 4230 is supplied with a supply voltage from the host 4100 and may be charged. The auxiliary power supply 4230 may provide the supply voltage of the SSD 4200 when the supply of power from the host 4100 is not smooth or consistent. For example, the auxiliary power supply 4230 may be located inside the SSD 4200 or located outside the SSD 4200. For example, the auxiliary power supply 4230 may be located on a main board and may provide auxiliary power to the SSD 4200.

The buffer memory 4240 functions as a buffer memory for the SSD 4200. For example, the buffer memory 4240 temporarily stores data received from the host 4100 or data received from the plurality of memory devices 4221 to 422n or may temporarily store metadata, for example, mapping tables, of the memory devices 4221 to 422n. The buffer memory 4240 may include volatile memories, such as a dynamic random access memory (DRAM), a synchronous DRAM (SDRAM), a double data rate (DDR) SDRAM, and a low power DDR (LPDDR) SDRAM, or nonvolatile memories, such as a ferroelectric RAM (FRAM), a resistive RAM (ReRAM), a spin transfer torque magnetic RAM (STT-MRAM), and a phase-change RAM (PRAM).

According to embodiments of the present disclosure, the strength of a memory device may be increased and bending of the memory device may be reduced by coupling material layers disposed inside a slit to a source line.

Concepts in conjunction with various embodiments are described above. Those skilled in the art will understand that various modifications, additions, and substitutions are possible, without departing from the scope and spirit of the present disclosure. Accordingly, the embodiments disclosed in the present specification should be considered not from a restrictive standpoint but rather from an illustrative standpoint. Therefore, the scope of the present disclosure should not be limited to the foregoing embodiments. All changes within the meaning and range of equivalency of the claims are to be included within their scope.

What is claimed is:

1. A memory device comprising:
a first stacked body spaced apart from a second stacked body by a slit;
a dummy layer configured to fill a portion of the slit and including a recess formed at a first end of the slit;
a plurality of spacers comprising a first spacer and a second spacer, wherein the first spacer is disposed between the dummy layer and the first stacked body, and the second spacer is disposed between the dummy layer and the second stacked body; and
a source line disposed over the first stacked body, the second stacked body, the dummy layer, and the plurality of spacers,
wherein each of the plurality of spacers comprises a protruding portion that extends away from the first stacked body and the second stacked body, and
wherein the source line fills the recess.

2. The memory device according to claim 1, wherein the dummy layer and the source line are formed of a similar material.

3. The memory device according to claim 1, wherein the dummy layer and the source line are formed of polysilicon.

4. The memory device according to claim 1, wherein the source line comprises:
a first portion disposed on the first stacked body and the second stacked body and above the slit, and
a second portion extending from the first portion and disposed inside the slit.

5. The memory device according to claim 4, wherein the second portion of the source line contacts the dummy layer between the first spacer and the second spacer.

6. The memory device according to claim 4, wherein a width of at least a part of the second portion of the source line narrows as the second portion extends away from the first end of the slit.

7. The memory device according to claim 1, wherein the source line encloses the protruding portion of each of the plurality of spacers.

8. The memory device according to claim 1, wherein:
each of the plurality of spacers comprises a penetrating portion, wherein the penetrating portion of the first spacer contacts the first stacked body and the penetrating portion of the first spacer contacts the second stacked body, and wherein the protruding portion extends from the penetrating portion, and
a width of the protruding portion is smaller than a width of the penetrating portion.

9. The memory device according to claim 1, further comprising plurality of cell plugs extending through the first stacked body and the second stacked body.

10. The memory device according to claim 9, wherein a channel layer included in each of the plurality of cell plugs contacts the source line.

11. The memory device according to claim 9, wherein a channel layer of each of the plurality of cell plugs extends away from the first stacked body and the second stacked body.

12. A method of manufacturing a memory device, the method comprising:
forming over a first substrate a first structure including a plurality of first material layers alternatively stacked with a plurality of second material layers;
forming a slit through the first structure;
replacing, through the slit, the plurality of second material layers with a plurality of third material layers;
forming a plurality of spacers along an outer periphery of the slit;
filling the slit between the spacers with a dummy layer;
removing at least a part of the first substrate;
forming a recess in the dummy layer by removing a portion of the dummy layer between the spacers; and
forming a source line filling the recess between the spacers.

13. The method according to claim 12, wherein forming the plurality of spacers comprises:
forming a spacer layer along a surface of the first substrate and an outer periphery of the slit; and
forming the plurality of spacers by removing the spacer layer formed on at least part of the surface of the first substrate.

14. The method according to claim 12, wherein forming the recess in the dummy layer comprises:
etching the first substrate; and
forming the recess by removing a portion of the dummy layer while the first substrate is etched.

15. The method according to claim 12, wherein, when a void is formed in the dummy layer while filling the dummy layer, the recess is formed such that the void is reduced.

16. The method according to claim 12, further comprising forming a plurality of cell plugs extending through the first structure.

17. The method according to claim 16, wherein forming the recess comprises removing the first substrate and the portion of the dummy layer such that a first end of each of the plurality of cell plugs and the plurality of spacers are exposed.

18. The method according to claim 17, further comprising, after forming the recess:
exposing a channel layer of each the plurality of cell plugs by removing exposed portions of each of the plurality of cell plugs; and
etching exposed portions of the plurality of spacers while the exposed portions of each of the plurality of cell plugs are removed.

19. The method according to claim 17, further comprising forming the source line to enclose exposed portions of the plurality of spacers.

20. The method according to claim 12, further comprising forming the source line to cover the plurality of spacers and the dummy layer.

21. The method according to claim 12, further comprising forming the source line to contact the dummy layer.

22. The method according to claim 12, further comprising turning the first structure upside down prior to forming the recess.

23. A method comprising:
forming a first stacked body spaced apart from a second stacked body by a slit;
forming a plurality of spacers within the slit and disposed between the first stacked body and the second stacked body;
forming a dummy layer between the spacers including a recess formed at a first end of the slit; and
forming a source line disposed over the first stacked body, the second stacked body, the dummy layer, and the plurality of spacers, wherein the source line fills the recess.
